(19) United States
(12) Patent Application Publication
(10) Pub. No.: US 2026/0215344 A1
(43) Pub. Date: Jul. 23, 2026

(54) DUAL-SIDED VERTICAL INTEGRATED VOLTAGE REGULATOR

(71) Applicant: Arm Limited, Cambridge (GB)

(72) Inventors: Javier DeLaCruz, San Jose, CA (US); Rainer Herberholz, Great Abington (GB); Yimajian Yan, Santa Clara, CA (US); Xingjian Cai, San Jose, CA (US); Stuart James Aitken, Cambridge (GB); Cameron Cole Nelson, Gilbert, AZ (US)

(21) Appl. No.: 19/406,274

(22) Filed: Dec. 2, 2025

Related U.S. Application Data
(60) Provisional application No. 63/748,398, filed on Jan. 22, 2025.

(51) Int. Cl. H10W 90/22; H05K 1/181; H05K 1/183; H10D 80/30; H10W 70/68; H10W 72/00; H10W 90/00; H10W 90/10; H10B 80/00

(52) U.S. Cl. CPC H10W 90/22; H05K 1/181; H05K 1/183; H10D 80/30; H10W 70/682; H10W 72/07236; H10W 90/10; H10W 90/401; H10W 90/724; H05K 2201/10325; H10B 80/00; H10W 90/754

(57) ABSTRACT

An integrated circuit assembly comprises an integrated circuit die comprising a first mounting surface, and a substrate having a first mounting surface and a second mounting surface opposite the first mounting surface. The first mounting surface of the substrate is electrically and physically coupled to the first mounting surface of the integrated circuit die, and the substrate further comprises a first plurality of electrical contact pads on the second mounting surface of the substrate. A vertically integrated voltage regulator has a first mounting surface and a second mounting surface opposite the first mounting surface, and is electrically and physically coupled to the substrate on the second mounting surface of the substrate and the first mounting surface of the vertically integrated voltage regulator. The voltage regulator further comprises a second plurality of electrical contact pads on the second mounting surface of the voltage regulator.

This application claims the benefit of priority to U.S. Provisional Ser. No. 63/748,398 titled “DUAL-SIDED VERTICAL INTEGRATED VOLTAGE REGULATOR,” and filed on January 22, 2025, which is incorporated herein by reference in its entirety.

### FIELD

The field relates to powering integrated circuit devices, and more specifically to a dual-sided vertical integrated voltage regulator for powering integrated circuits.

### BACKGROUND

Modern computerized devices process and store information in a variety of ways, including using processors that may have multiple cores and cache memory that may be associated with each of at least some of the processor cores. The processors in modern high-performance consumer electronics devices such as smart phones, tablet computers, set top boxes, and the like, may have different processor cores with different capabilities, such as high-performance processor cores that can perform a high number of operations per second but that may consume a significant amount of power, and efficient cores that may perform tasks more efficiently but at a lower peak number of instructions per second than high performance cores. In some further examples, at least some of the high-performance cores and/or efficient cores may have configurable performance levels, such as underdriven or overdriven voltage levels and corresponding faster or reduced operating speeds.

Processor cores in some examples may be powered up or down as needed, and in further examples may have one or more different available performance levels (and associated efficiency levels) per core. For example, a demanding video game involving rendering many objects in real time may use both high-performance cores and all the high-efficiency cores in a smartphone, while a simple task like reading email may use a single high-efficiency core. Cores may therefore be selectively powered up or selectively employed to process program instructions depending on the task load in a computing device, typically involving significant changes in power demand as different processor cores are made active or employed to process instructions.

A large integrated circuit die may also have variances in semiconductor behavior across the die or between dies (sometimes known as process corner variances), and voltages needed for different clock frequencies or performance levels of different cores may also vary significantly. Individual control of voltages for each processor core or group of processor cores is therefore desirable in some multi-core computing systems to minimize power consumption by providing each core with no more than the voltage required for reliable operation at a given performance level or clock frequency. High granularity of voltage level provided to different processor cores in a computing system via voltage regulation external to the integrated circuit die may simplify power delivery to the die, but may present challenges related to the physical wire distance and impedance between the voltage regulator and the integrated circuit die.

Multi-core processors in modern computing systems may also have their own cache memory, such as a dedicated level one (L1) or level two (L2) cache memory associated with some or all of the respective processor cores in the multi-core processor. L1 or L2 cache local to one or more processor cores may store frequently-used data local to the respective cores, which may make retrieval of this often-used data faster than if the same data was retrieved from Level 3 (L3) cache or main memory (or DRAM) that is typically slower and physically more remote. Cache memory may typically contain tens of thousands or hundreds of thousands (or more) of words of data per core, comprising a significant percentage of the die area, transistor count, and power consumed by the integrated device, and may be powered up and down or switched between active and inactive power states as processor cores are powered up and down.

When processor cores are powered on to provide greater computing resources for a computing system, they may quickly draw significantly more current than before the cores and cache were powered, potentially causing a droop in voltage provided to the processor circuits. High-performance application such as servers configured to process artificial intelligence workloads may further contain thousands of cores, including hundreds of cores per integrated circuit, drawing power exceeding a kilowatt. Providing power to such cores through a voltage regulator on a motherboard may present some difficulty due to the physical distance and impedance between the voltage regulator circuitry and the integrated circuit die. Voltage regulators are often therefore designed to provide high current capability to an integrated circuit die while limiting effects such as voltage droop. But, voltage regulator circuitry may be slow to respond due to factors such as physical distance and impedance between the voltage regulator and integrated circuit. For reasons such as these, a need exists for improved voltage supply and regulation in powering integrated circuits such as processor cores and associated cache memory.

### BRIEF DESCRIPTION OF THE DRAWINGS

The claims provided in this application are not limited by the examples provided in the specification or drawings, but their organization and/or method of operation, together with features, and/or advantages may be best understood by reference to the examples provided in the following detailed description and in the drawings, in which:

FIG. 1 is a side view of an integrated circuit package comprising a substrate configured to receive a dual-sided vertically integrated voltage regulator, consistent with an example embodiment.

FIG. 2 is a side view of an integrated circuit package comprising a substrate coupled to a dual-sided vertically integrated voltage regulator, consistent with an example embodiment.

FIG. 3 is a side view of an integrated circuit package comprising a substrate coupled to a dual-sided vertically integrated voltage regulator and a spacer, consistent with an example embodiment.

FIG. 4 is a side view of an integrated circuit package comprising a dual-sided vertically integrated voltage regulator and a spacer coupled to a printed circuit board, consistent with an example embodiment.

FIG. 5 is a side view of an integrated circuit package comprising a dual-sided vertically integrated voltage regulator configured between a substrate and a printed circuit board, consistent with an example embodiment.

FIG. 6 is a side view of an integrated circuit package comprising a dual-sided vertically integrated voltage regulator received in a socket, consistent with an example embodiment.

FIG. 7 is a flow diagram of a method of assembling an integrated circuit with a dual-sided vertically integrated voltage regulator, consistent with an example embodiment.

FIG. 8 shows a block diagram of a general-purpose computerized system, consistent with an example embodiment.

FIG. 9 is a cross-section scale view of an integrated circuit assembly having a spacer and a dual-sided voltage regulator, consistent with an example embodiment.

FIG. 10 a cross-section scale view of an integrated circuit assembly having a dual-sided voltage regulator and a socket, consistent with an example embodiment.

Reference is made in the following detailed description to accompanying drawings, which form a part hereof, wherein like numerals may designate like parts throughout that are corresponding and/or analogous. The figures have not necessarily been drawn to scale, such as for simplicity and/or clarity of illustration. For example, dimensions of some aspects may be exaggerated relative to others. Other embodiments may be utilized, and structural and/or other changes may be made without departing from what is claimed. Directions and/or references, for example, such as up, down, top, bottom, and so on, may be used to facilitate discussion of drawings and are not intended to restrict application of claimed subject matter. The following detailed description therefore does not limit the claimed subject matter and/or equivalents.

### DETAILED DESCRIPTION

In the following detailed description of example embodiments, reference is made to specific example embodiments by way of drawings and illustrations. These examples are described in sufficient detail to enable those skilled in the art to practice what is described, and serve to illustrate how elements of these examples may be applied to various purposes or embodiments. Other embodiments exist, and logical, mechanical, electrical, and other changes may be made.

Features or limitations of various embodiments described herein, however important to the example embodiments in which they are incorporated, do not limit other embodiments, and any reference to the elements, operation, and application of the examples serve only to aid in understanding these example embodiments. Features or elements shown in various examples described herein can be combined in ways other than shown in the examples, and any such combinations is explicitly contemplated to be within the scope of the examples presented here. The following detailed description does not, therefore, limit the scope of what is claimed.

Many modern computing systems employ processors with multiple processing cores, such that certain tasks that can be performed in parallel can be distributed among the cores for faster execution or different tasks can be performed simultaneously by different processors. Simple tasks such as checking an email may only use one processor core, while more complex tasks such as rendering a video game in real time may use all available cores. The processor cores in further examples may be associated with cache memory local to one or more of the respective processor cores, operable to store information that the processor core is likely to need for executing program instructions using local SRAM for fast access.

In some examples the different processor cores may also include different types of circuits, such as high performance processor cores, high efficiency processor cores, memory, and other such circuits. These circuits may vary in power demand, in physical location on the die, and on power demand per unit of area on the die. Powering processor cores and their related caches up and down changes the current drawn from the power source for the processor cores (and, in some further examples, associated cache memory), and may cause a temporary droop in supplied voltage while the voltage regulator or other power supply components recover from the increased demand for power. This voltage droop may be controlled to some degree using methods such as a low-dropout voltage regulator that responds somewhat quickly to changes in drawn current, by using bypass capacitors to store extra charge that is available to help meet a sudden demand for additional current, or through other such means. But, the impedance of low-dropout voltage regulator and the distance between the voltage regulator and the integrated circuit die may limit its ability to respond quickly to changes in power demand. Problems such as these may be exacerbated by high-performance or high-density integrated circuit devices, such as integrated circuits holding hundreds of processor cores for machine learning processing that may consume hundreds or thousands of watts of power.

Although voltage regulators used to power integrated circuits such as high-performance processors may be placed physically near the integrated circuit to reduce the impedance between the voltage regulator and the integrated circuit, power signal traces between a voltage regulator and an integrated circuit through a printed circuit board or substrate may still be longer than the largest dimension of the voltage regulator or the integrated circuit being powered, resulting in significant impedance between the voltage regulator and the integrated circuit

Some examples presented herein therefore provide for an improved dual-sided voltage regulator for integrated circuit dies and packages, comprising a voltage regulator assembly that has electrical connections on opposing mounting surfaces of the voltage regulator. The voltage regulator may be connected to an integrated circuit die or to a substrate coupled to an integrated circuit die on a first mounting surface, and may be coupled to a power source such as via a printed circuit board or socket on a second mounting surface opposite the first mounting surface.

In a more detailed example, an integrated circuit assembly comprises an integrated circuit die and a substrate having a first mounting surface and a second mounting surface opposite the first mounting surface. The substrate is electrically and physically coupled to the integrated circuit die on a first mounting surface of the die and the first mounting surface of the substrate. A voltage regulator has a first mounting surface and a second mounting surface opposite the first mounting surface, and the voltage regulator is electrically and physically coupled to the substrate on the second mounting surface of the substrate and the first mounting surface of the voltage regulator. A spacer has a first mounting surface and a second mounting surface opposite the first mounting surface, and is electrically and physically coupled to the substrate on the first mounting surface of the spacer and the second mounting surface of the substrate. The spacer further comprises a plurality of electrical connections passing through the spacer from the first mounting surface of the spacer to the second mounting surface of the spacer, and the second mounting surface of the voltage regulator is approximately coplanar with the second mounting surface of the spacer.

In another example, an integrated circuit assembly comprises an integrated circuit die having a first mounting surface and a substrate having a first mounting surface and a second mounting surface opposite the first mounting surface. The first mounting surface of the integrated circuit die is physically and electrically connected to the first mounting surface of the substrate. The substrate comprises a plurality of electrical contacts on the second mounting surface of the substrate configured to electrically connect with a first plurality of electrical connections in a socket. A voltage regulator having a first mounting surface and a second mounting surface opposite the first mounting surface is electrically and physically coupled to the substrate on the second mounting surface of the substrate and the first mounting surface of the voltage regulator. The voltage regulator further comprises a plurality of electrical contacts on the second mounting surface of the voltage regulator configured to electrically connect with a second plurality of electrical connections in the socket.

Examples such as these illustrate how a dual-sided vertically integrated voltage regulator assembly can be mounted physically near an integrated circuit die, shortening the length and reducing the impedance of electrical connections between the voltage regulator and the integrated circuit die. Such an assembly may allow the voltage regulator to more quickly respond to changes in observed voltage on the integrated circuit die, such as during transients or rapid changes in drawn current, and may provide for more efficient delivery of power to the integrated circuit die with less loss, delay, and other impedance-related or distance-related artifacts.

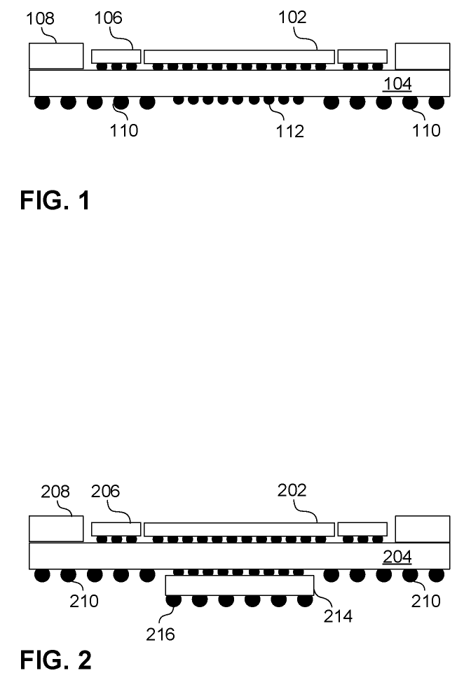

FIG. 1 is a side view of an integrated circuit package comprising a substrate configured to receive a dual-sided vertically integrated voltage regulator, consistent with an example embodiment. Here, an integrated circuit die 102 is electrically and physically coupled to a substrate 104. The integrated circuit may in various embodiments comprise various digital analog, or mixed circuits. Digital circuit examples include one or more processor cores, graphics processors, memory, signal processors, and other digital circuits, while analog circuit examples include amplifiers, filters, analog communication circuits, and the like. Mixed signal integrated circuits may contain both digital and analog circuits on the same device, such as a wireless networking integrated circuit operable to process both analog radio waves and digital data signals to facilitate transmission and/or reception of digital data using analog radio waves. The substrate 104 in various examples may comprise a fiberglass and resin, organic laminate, ceramic, or other suitable material, and may contain within one or more conductive layers comprising various signal, power, and other electrical interconnects coupling the flip-chip bumps to ball grid array (BGA) solder balls, Land Grid Array (LGA) contact pads, Pin Grid Array pins, or other package electrical connections.

The substrate 104 in this example also supports high speed memory 106, which may be a chiplet or integrated circuit die separate from the processor and providing the processor with relatively high speed and low latency memory. The high speed memory in a more detailed example may comprise static random access memory or SRAM, and may be used for cache memory such as a level 1 (L1), level 2, (L2), or level 3(L3) cache. The substrate may further be physically attached to a stiffener 108, configured to help the substrate 104 resist deflection such as during heat cycles of solder reflow due to differences in coefficient of thermal expansion between the substrate 104 and the integrated circuit die 102.

The bottom surface of the substrate 104 comprises a plurality of electrical interconnects configured to couple the electrical connections to the integrated circuit 102 to connections on a printed circuit board and a voltage regulator. The electrical connections in the example of FIG. 1 are ball grid array solder bumps, which may be melted such as in a solder reflow oven to physically and electrically connect the substrate 104 to a printed circuit board and to a voltage regulator assembly. The solder bumps in the example of FIG. 1 form two distinct groups or arrays, including circuit board solder bumps 110 and voltage regulator solder bumps 112. These solder bumps in various examples may comprise solder-coated pillars or solder-coated metal balls, such as solder-coated copper balls used to improve consistent spacing and conductivity of the connections between layers. In other examples, pins, spring-loaded contacts, or other such electrical connections may similarly be employed.

FIG. 2 is a side view of an integrated circuit package comprising a substrate coupled to a dual-sided vertically integrated voltage regulator, consistent with an example embodiment. Here, the integrated circuit assembly comprises an integrated circuit 202 coupled to a substrate 204 by an array of electrical contacts such as a flip chip ball grid array, and one or more high speed memory chiplets 206 further coupled to the substrate via a flip chip ball grid array or other electrical connections. The substrate 204 may comprise electrical connections including metal traces, vias, plated-through holes, and the like to couple components such as the integrated circuit 202 and the high speed memory 206.

A stiffener 208 is also attached around an edge of the substrate 204, improving the stiffness of the substrate to resist warping during heating and cooling such as due to a difference in coefficient of thermal expansion between the integrated circuit die 202 and the substrate 204. The substrate further comprises arrays of electrical connections on the side opposite the integrated circuit, much like the circuit board solder balls 110 and voltage regulator solder balls 112 of FIG. 1.

In the example shown here, a dual-sided voltage regulator 214 is coupled to the substrate via the voltage regulator solder bumps, and is operable to provide at least one regulated voltage supply to the integrated circuit 202 via the substrate 204. The voltage regulator in a more detailed example may comprise one or more inductors, one or more capacitors, a voltage regulation circuit, and other such circuitry as needed to provide a desired or requested voltage to the integrate circuit. The voltage regulator 214 in various embodiments may be operable to monitor one or more voltage signals on the integrated circuit die 202, and/or monitor one or more voltage signals provided from the voltage regulator assembly to the integrated circuit die. The voltage regulator in various examples may be a Low-Dropout Voltage Regulator (LDO voltage regulator) operable to regulate output voltages that are very close to the supply voltage, a linear voltage regulator, or other type of suitable voltage regulator. The voltage regulator may in further examples comprise a DC to DC voltage converter, such as a buck converter or other suitable voltage converter circuit. The voltage regulator circuit in various examples may include one more power components such as one or more inductors (and/or capacitors), which may be physically large relative to other voltage regulator assembly components and so may be external to the voltage regulation circuit 214.

The voltage regulator 214 may be physically and electrically coupled to the substrate 204 by a ball grid array of solder balls, such as voltage regulator solder balls 112, to send power signals and exchange other signals such as telemetry (e.g., measured voltages) and control information (e.g. desired output voltage) with the integrated circuit 202 on a first mounting surface of the dual-sided voltage regulator. The voltage regulator may have an array of electrical contacts 216 on a second mounting surface opposite the first mounting surface of the voltage regulator to receive power signals (e.g., a high voltage power supply input) from a printed circuit board. In the example shown here, the array of electrical contacts 216 may be of a different pitch than the flip chip ball grid array of voltage regulator solder balls 112 coupling the substrate to the voltage regulator, such as where connections between the substrate and printed circuit board may use a larger pitch (such as 1mm) than the flip-chip ball grid array pitch (such as 0.5mm) due to the relatively larger area of the substrate and possible warping of the substrate and printed circuit board and substrate during solder reflow.

In some examples, solder reflow may be performed multiple times in configuring an integrated circuit assembly, such as a first solder reflow to attach the integrated circuit and high performance memory to the substrate as shown in FIG. 1, a second solder reflow to attach the voltage regulator 214 to the substrate, and the like. Mounted components may be underfilled with a material such as epoxy once mounted to prevent movement or disconnection during subsequent solder reflows, such as underfilling the gaps between the substrate 104 of FIG. 1 and the integrated circuit 102 and high performance memory 106 chips before proceeding with a reflow to mount the voltage regulator 214 as shown in FIG. 2.

Once the voltage regulator is attached to the substrate 204 such as by solder reflowing the ball grid array of solder balls and underfilling with epoxy, the assembly shown in FIG. 2 comprises a die, a substrate, and a dual-sided vertically integrated voltage regulator mounted to the substrate on an opposite side of the substrate from where the integrated circuit die is mounted. The voltage regulator 214 is physically near the integrated circuit, separated only by the substrate 204 and the electrical contacts coupling the substrate to the voltage regulator and the integrated circuit. In a more detailed example, the voltage regulator 214 and the integrated circuit die 202 at least partially overlap, such that at least a portion of the voltage regulator and at least a portion of the integrated circuit die are intersected by an axis normal to and through the first mounting surface of the voltage regulator and the first mounting surface of the integrated circuit die.

This brings the voltage regulator 214 physically very close to the integrated circuit 202, but has the disadvantage of interrupting the array of contacts on the substrate configured to be connected to a printed circuit board, represented here by circuit board solder bumps 210 and providing an irregular or non-flat mounting surface across the bottom of the substrate 204 due to the presence of the voltage regulator 214. This challenge may be addressed in various examples presented herein by use of a spacer to extend the circuit board solder bumps 210 to be approximately in the same plane as the electrical contacts 216 on the second mounting surface of the voltage regulator, by using a socket configured with a cavity and electrical contacts to accommodate the dual-sided voltage regulator, or the like.

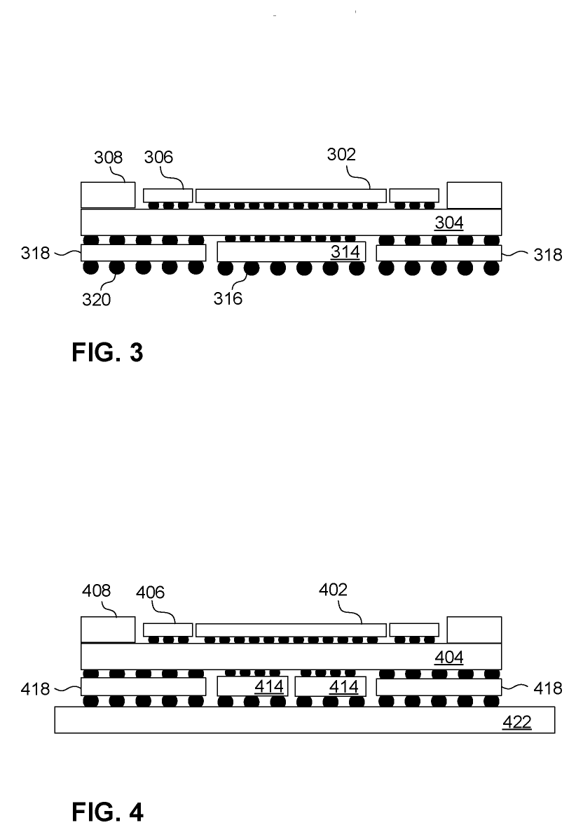

FIG. 3 is a side view of an integrated circuit package comprising a substrate coupled to a dual-sided vertically integrated voltage regulator and a spacer, consistent with an example embodiment. Here, an integrated circuit assembly comprises an integrated circuit die 302, a high speed memory 306, and a stiffener 308 coupled to a substrate 304. A dual-sided voltage regulator 314 is coupled to the opposite of the substrate opposite the integrated circuit 302, much as in the example of FIG. 2.

Because the array of electrical contacts 216 on the opposite side of the voltage regulator from the substrate are not in plane with the array of substrate solder balls 210 in FIG. 2, a spacer 318 may be added to the example of FIG. 3 such that the electrical contacts on the bottom side of the voltage regulator are approximately coplanar with the electrical contacts 320 on the bottom side of the spacer 318. The electrical contacts on the top of the spacer in this example may be directly connected to corresponding electrical contacts on the bottom or opposite side of the spacer, while other examples may provide for a change in contact array pitch (such as redistributing a finer pitch on the substrate to a coarser pitch on the printed circuit board), connecting multiple electrical contacts such as grounds together, embedding one or more electrical components such as capacitors, or other such configuration changes.

The pitch of electrical contacts connecting the spacer to the substrate and to a printed circuit board, such as a ball grid array of solder balls as shown at 320, may be a wider pitch than other solder balls arrays such as a flip chip ball grid array used to mount smaller devices such as the voltage regulator or integrated circuit to the substrate due at least in part to the relatively larger size of the substrate and the increased potential for warping or other misalignment when attaching via reflow of ball grid arrays of solder balls. In a more detailed example, solder ball connections to the spacer or to a printed circuit board may have a pitch of approximately 1mm between solder balls, while solder ball connections to smaller components such as the integrated circuit or voltage regulator may have a smaller pitch of approximately .5mm between solder balls.

The solder ball pitch may be related to electrical contact pad or land size on the various components to be connected via ball grid arrays of solder balls, and may also influence other solder ball dimensions such as solder ball diameter and solder ball height after reflow. In a more detailed example, a 1mm pitch solder ball array may have solder balls of .5mm to .6mm in height after reflow, such that a gap of approximately .55mm should be accommodated above and below the spacers 318 and between the bottom side of the voltage regulator 314 and a printed circuit board. Smaller solder balls, finer pitches, and smaller gaps between components after reflow may be employed with smaller devices, such as where the voltage regulator 314 or the integrated circuit 302 are connected to the substrate 304. The gap between the voltage regulator 314 and the substrate 304 may therefore be smaller than the gap between the spacer 318 and the substrate 304, and it may be desirable to account for such differences in determining parameter such as the desired height or thickness of the spacer 318.

The allowable or desirable tolerance for electrical contacts 316 on the bottom of the voltage regulator being in plane with the contacts on the bottom of spacer 320 may similarly be dependent on factors such as the pitch between solder balls, the height of the solder balls after reflow, the size of the pads or lands to which the solder balls adhere, and the like. In one such example, solder balls having a pitch of 1mm between solder balls and an approximate thickness of .55mm after reflow may desirably be within .05mm .10mm, or .15mm of being in the same plane .55mm above the printed circuit board. The allowable or desirable tolerance in some examples may also be influenced by the size of the substrate, and the degree to which the substrate may warp during or after reflow.

The spacer 318 in some embodiments may comprise a structure other than a substrate with solder balls attached as is shown in FIG. 3, such as solder-coated metal pillars that provide consistent spacing and high conductivity between the substrate 304 and a printed circuit board. The spacer in other embodiments may comprise solder bumps without metal pillars, a socket or other such mounting structure, or other structure providing sufficient space between the substrate 304 and a printed circuit board to accommodate voltage regulator 314.

FIG. 4 is a side view of an integrated circuit package comprising a dual-sided vertically integrated voltage regulator and a spacer coupled to a printed circuit board, consistent with an example embodiment. Here, an integrated circuit assembly includes an integrated circuit die 402, high speed memory 406, and a stiffener 408 mounted to a first mounting surface of a substrate 404. A second mounting surface of the substrate opposite the first mounting surface is electrically and physically coupled to one or more voltage regulators 414 and one or more spacers 418, such that the surfaces of the spacers and the voltage regulators opposite the spacer are approximately coplanar, much as in the example of FIG. 3.

The one or more voltage regulators 414 and one or more spacers 418 are here electrically and physically coupled to a printed circuit board 422, such as a system board in a computer or the like. The printed circuit board may connect the integrated circuit to other devices such as external memory, storage, input/output, and the like, and may provide power to the integrated circuit. In a more detailed example, the printed circuit board may carry common voltages such as 5V, 3.3V, and/or 1.5V to various components of an electronic device such as a computer, and may supply one or more of such voltage signals to voltage regulators 414 via the ball grid array of solder balls that electrically and physically couple the voltage regulators to the printed circuit board.

The example of FIG. 4 shows multiple voltage regulators, which in various embodiments may supply different voltages for different processor cores, for different groups of processor cores such as efficient vs. performance processor cores, or for other different voltage domains. In a more complex example, the integrated circuit 402 may comprise several processor cores and may have several voltage regulators, such as one voltage regulator per core or one voltage regulator per group of cores, such that the various processor cores may request and receive different voltages depending on their particular needs. The processor cores (or other circuits) on the integrated circuit die may further provide telemetry to the voltage regulator, such as the requested voltage, the measured voltage provided, the current drawn, and/or other such telemetry.

The spacer 418 in the cross section example of FIG. 4 appears to be two different sections, but in some embodiments may comprise a closed loop encircling the one or more voltage regulators 414. In a more detailed example, the spacer comprises a polygon such as a square or rectangle outside profile, which may correspond with the size and shape of the substrate 404, the size or shape of the ball grid array of electrical contacts on the substrate 404, or other such shape. The spacer in the example as shown here may further comprise an opening or a cutout to accommodate the one or more voltage regulators, such as a square, rectangular, or other-shaped opening in the spacer to accommodate the voltage regulators and their electrical connections.

The dual-sided vertically integrated voltage regulators shown in FIG. 4 have very short electrical connections between the voltage regulators 414 and the integrated circuit 402, such that the electrical connections have a relatively low impedance. This enables relatively rapid response to detected or requested changes in voltage in the integrated circuit die 402, and relatively low losses due to impedance or physical distance between the dual-sided vertically integrated voltage regulator and the integrated circuit die. The configuration of FIG. 4 may therefore be able to respond to changes in power demand, such as may cause voltage transients, better than other known configurations, and may experience less loss or delay in responding to changes in power demand due to the physical proximity and reduced impedance between the vertically integrated voltage regulator and the integrated circuit die.

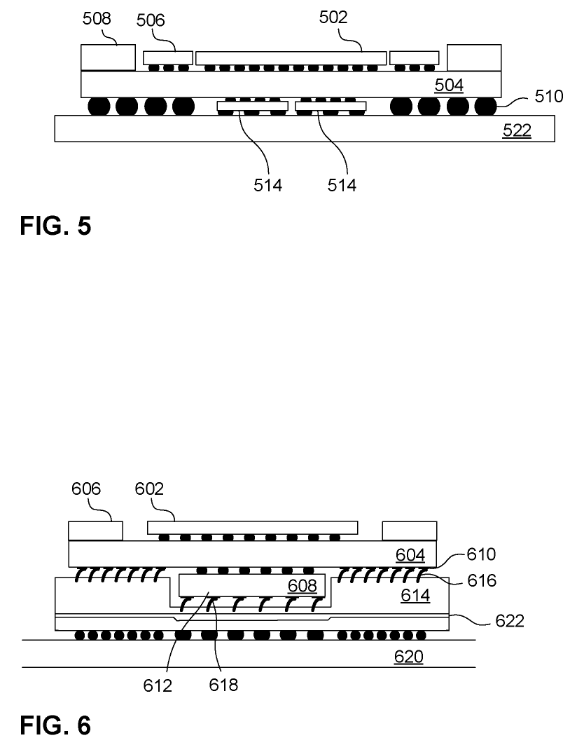

FIG. 5 is a side view of an integrated circuit package comprising a dual-sided vertically integrated voltage regulator configured between a substrate and a printed circuit board, consistent with an example embodiment. Here, an assembly much like the assembly of FIG. 4 is shown, except that spacer 418 is omitted and the voltage regulators 514 are thin enough that such a spacer is not employed, and solder bumps 510 provide sufficient electrical and physical connection between printed circuit board 522 and substrate 504. In a further example, solder bumps 510 may comprise metal pillars or metal balls coated with solder, such as copper balls coated with solder, providing both improved conductivity and uniform spacing between the substrate 504 and the printed circuit board 522, or may comprise another such electrical and/or physical connection between the substrate and the printed circuit board.

FIG. 6 is a side view of an integrated circuit package comprising a dual-sided vertically integrated voltage regulator received in a socket, consistent with an example embodiment. Here, an integrated circuit 602 is mounted to a substrate 604, such as using a flip-chip ball grid array. A stiffener 606 is physically coupled to the edges of the substrate 604, and helps the substrate resist warping, such as during solder reflow due to differences in coefficient of thermal expansion between the integrated circuit 602 and the substrate 604. The substrate has contact pads or lands 610 on a surface opposite the surface to which the integrated circuit is mounted, configured to mate with a socket such as a Land Grid Array (LGA) socket or the like. A dual-sided vertically integrated voltage regulator is shown at 608, and is coupled to the substrate 604 on a first mounting surface of the voltage regulator and has contact pads or lands 612 further configured to mate with electrical contacts in a socket. The voltage regulator may be considered dual-sided in that it has contacts on both its top side and its bottom side as shown in FIG. 6, including top side contacts configured to be coupled to the substrate 604 and bottom side contacts configured to mate with electrical contacts in a socket.

A socket 614 comprises a substrate array of electrical contacts 616 configured to mate with the substrate contacts or land pads 610, and a voltage regulator array of electrical contacts 618 configured to mate with the voltage regulator lands or pads 612. In some examples, the contacts 616 and/or 618 may comprise biased spring arms, such as a traditional land grid array or LGA socket, while on other examples the contacts may comprise spring-loaded pins, levers or beams with a spring bias, or other such electrical contacts. In a further example, at least some of the electrical contacts such as the voltage regulator contacts 618 and 612 may be configured as high current contacts, such as where the contacts connect with a greater surface area. A variety of commercial contacts addressing such current-carrying capacity exist, such as Nanowire contact, Fuzz Button-style contacts, and the like, and may be used in some embodiments to improve current handling capability where high current is expected. The physical size, pitch, or other physical dimensions of the voltage regulator contacts 612 and 618 may therefore be larger than signal contacts such as 610 and 516, enabling the voltage regulator contacts to carry higher current. The socket 614 in this example is connected to a printed circuit board 620, such as by solder balls in a ball grid array, by pins, or by other such means, which provides for communication of data, power, and other such signals between the integrated circuit 602 and other circuitry in an electronic system. The pitch and/or physical size of electrical connections between the socket and the printed circuit board may vary in some examples, such as using larger connections capable of carrying more current and having a larger pitch between connections to connect the printed circuit board to voltage regulator contacts 618 than to signal contacts 616.

In the example shown here, the integrated circuit assembly is installed in a socket 614, such that substrate lands 610 mate with substrate contacts 616 on the socket, and voltage regulator lands 612 mate with voltage regulator contacts 618 on the socket. Although the example of FIG. 6 shows spring arms as socket contacts 616 and 618, other examples may comprise spring-biased pins, high current contacts, or other contacts as described in the example of FIG. 5. The substrate contact 616 and the voltage regulator contacts 618 on the socket may be operable to connect the integrated circuit assembly components to other circuitry on the printed circuit board, such as memory, input/output, power signals, and the like.

The socket 614 as shown in FIG. 6 further includes a liquid cooling channel 622, such that a liquid such as water, glycol, or the like may be circulated through the socket to draw heat away from the socket, and consequently away from the voltage regulator 608 and the integrated circuit die 602. In a further example, a thermal interface between the socket 620 and at least one component such as voltage regulator 608 may be provided to better conduct heat from the component to the socket, such as a nonconductive thermal paste. The liquid cooling channel 622 may receive a cooling fluid at one end, such as via a pump, and circulate the fluid at least in an area of anticipated heat such as near the voltage regulator 608. In some examples, the liquid cooling channel 622 may zig-zag in the area where cooling is desired, may have a greater volume in the area where cooling is desired, may be split into multiple channels in the area where cooling is desired, or may otherwise be configured to improve heat flow between the socket and the cooling liquid. The cooling liquid exiting the socket may be returned to a heat exchanger, such as a fan-cooled radiator, a liquid-to-liquid heat exchanger, or the like, in which heat may be removed from the cooling liquid before being recirculated back to the socket 614.

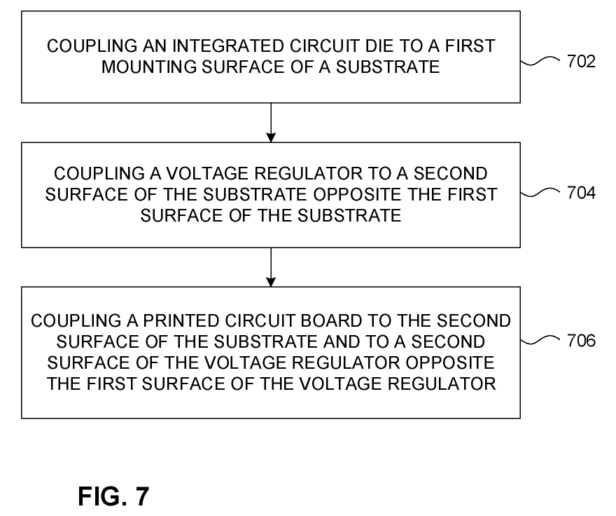

FIG. 7 is a flow diagram of a method of assembling an integrated circuit with a dual-sided vertically integrated voltage regulator, consistent with an example embodiment. At 702, an integrated circuit die such as a processor or other circuit die is electrically and physically coupled to a first mounting surface of a substrate, such as via a flip-chip ball grid array. In further examples, other components such as other integrated circuits or chiplets, discrete components such as capacitors, or structural components such a stiffener and/or a lid may further be coupled to the first mounting surface of the substrate.

A voltage regulator is coupled to a second surface of the substrate opposite the first surface of the substrate at 704, such as via a flip-chip ball grid array. Internal connections in the substrate couple the voltage regulator with the integrated circuit, such that the voltage regulator supplies a regulated voltage signal to power the integrated circuit. In a further example, the voltage regulator may exchange other signals with the integrated circuit, such as a requested voltage, an observed voltage, or other such metrics.

The voltage regulator in some examples may comprise multiple independent voltage regulators, which may or may not be embodied on separate semiconductor chips or other physical modules or substrates. The voltage regulators may provide different voltages to different circuits, such as to different processor cores on an integrated circuit or to different types of processors or different groups of circuits on the integrated circuit.

At 706, a printed circuit board is coupled to the second surface of the substrate and to a second surface of the voltage regulator opposite the first surface of the voltage regulator. The connections between the printed circuit board and the substrate may serve to connect the integrated circuit’s electrical connections to other circuitry on the printed circuit board, such as memory, input/output, and the like. The connections between the printed circuit board and the substrate may provide power to the voltage regulator that the voltage regulator may use to provide a regulated voltage signal to the integrated circuit die.

The connections between the printed circuit board and the voltage regulator and substrate may take the form of a socket in some examples, or may be connected via a spacer or other such mechanism to ensure that the contacts on the second surface of the voltage regulator and the second surface of the substrate as extended by the spacer are approximately coplanar. In some examples, the socket may be configured to accommodate a voltage regulator having a second surface that is not coplanar with the second surface of the substrate, such as is shown in the examples of FIGS. 5 and 6.

The examples presented herein illustrate how a dual-sided vertically integrated voltage regulator may be positioned physically near an integrated circuit die such that signal travel distance and signal impedance between the vertically integrated voltage regulator and the integrated circuit die are low. In one example, a spacer may be used to ensure that the contacts on the second surface of the voltage regulator and the second surface of the substrate as extended via the spacer are approximately coplanar. In another example, a socket may be configured to accommodate a voltage regulator having a second surface that is not coplanar with the second surface of the substrate.

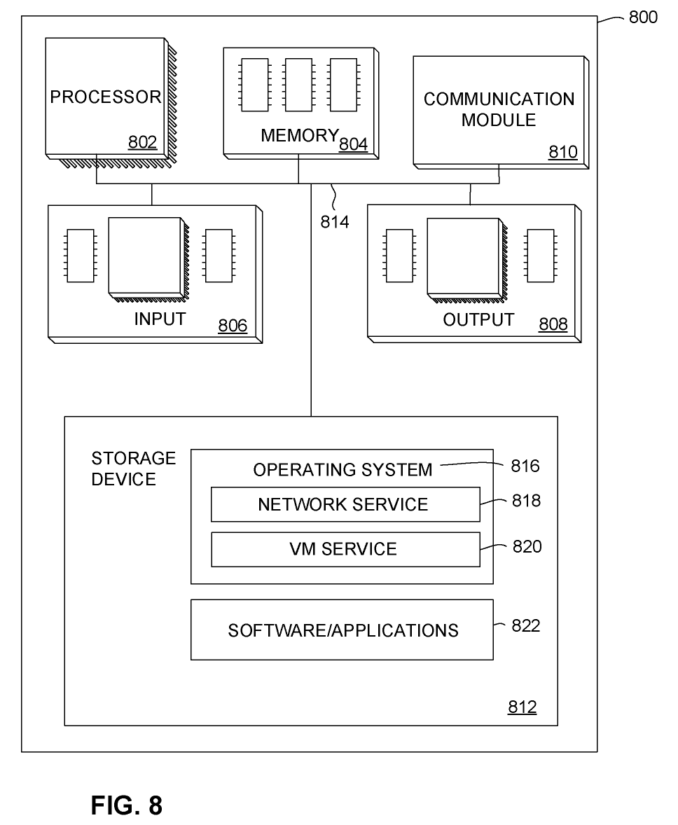

FIG. 8 shows a block diagram of a general-purpose computerized system, consistent with an example embodiment. FIG. 8 illustrates only one particular example of computing device 800, and other computing devices 800 may be used in other embodiments. Although computing device 800 is shown as a standalone computing device, computing device 700 may be any component or system that includes one or more processors or another suitable computing environment for executing software instructions in other examples, and need not include all of the elements shown here.

As shown in the specific example of FIG. 8, computing device 800 includes one or more processors 802, memory 804, one or more input devices 806, one or more output devices 808, one or more communication modules 810, and one or more storage devices 812. Computing device 800, in one example, further includes an operating system 816 executable by computing device 800. The operating system includes in various examples services such as a network service 818 and a virtual machine service 820 such as a virtual server. One or more applications, such as application 822 are also stored on storage device 812, and are executable by computing device 800.

Each of components 802, 804, 806, 808, 810, and 812 may be interconnected (physically, communicatively, and/or operatively) for inter-component communications, such as via one or more communications channels 814. In some examples, communication channels 814 include a system bus, network connection, inter-processor communication network, or any other channel for communicating data. Applications such as software application 822 and operating system 816 may also communicate information with one another as well as with other components in computing device 800.

Processors 802, in one example, are configured to implement functionality and/or process instructions for execution within computing device 800. For example, processors 802 may be capable of processing instructions stored in storage device 812 or memory 804. Examples of processors 802 include any one or more of a microprocessor, a controller, a central processing unit (CPU), a graphics processing unit (GPU), a neural processing unit (NPU), an image signal processor (ISP), a digital signal processor (DSP), an application specific integrated circuit (ASIC), a field-programmable gate array (FPGA), or similar discrete or integrated logic circuitry.

One or more storage devices 812 may be configured to store information within computing device 800 during operation. Storage device 812, in some examples, is known as a computer-readable storage medium. In some examples, storage device 812 comprises temporary memory, meaning that a primary purpose of storage device 812 is not long-term storage. Storage device 812 in some examples is a volatile memory, meaning that storage device 812 does not maintain stored contents when computing device 800 is turned off. In other examples, data is loaded from storage device 812 into memory 804 during operation. Examples of volatile memories include random access memories (RAM), dynamic random access memories (DRAM), static random access memories (SRAM), and other forms of volatile memories known in the art. In some examples, storage device 812 is used to store program instructions for execution by processors 802. Storage device 812 and memory 804, in various examples, are used by software or applications running on computing device 800 such as software application 822 to temporarily store information during program execution.

Storage device 812, in some examples, includes one or more computer-readable storage media that may be configured to store larger amounts of information than volatile memory. Storage device 812 may further be configured for long-term storage of information. In some examples, storage devices 812 include non-volatile storage elements. Examples of such non-volatile storage elements include magnetic hard discs, optical discs, floppy discs, flash memories, or forms of electrically programmable memories (EPROM) or electrically erasable and programmable (EEPROM) memories.

Computing device 800, in some examples, also includes one or more communication modules 810. Computing device 800 in one example uses communication module 810 to communicate with external devices via one or more networks, such as one or more wireless networks. Communication module 810 may be a network interface card, such as an Ethernet card, an optical transceiver, a radio frequency transceiver, or any other type of device that can send and/or receive information. Other examples of such network interfaces include Bluetooth, 4G , LTE, or 5G, WiFi radios, and Near-Field Communications (NFC), and Universal Serial Bus (USB). In some examples, computing device 800 uses communication module 810 to wirelessly communicate with an external device such as via a public network.

Computing device 800 also includes in one example one or more input devices 706. Input device 806, in some examples, is configured to receive input from a user through tactile, audio, or video input. Examples of input device 806 include a touchscreen display, a mouse, a keyboard, a voice responsive system, video camera, microphone or any other type of device for detecting input from a user.

One or more output devices 808 may also be included in computing device 800. Output device 808, in some examples, is configured to provide output to a user using tactile, audio, or video stimuli. Output device 808, in one example, includes a display, a sound card, a video graphics adapter card, or any other type of device for converting a signal into an appropriate form understandable to humans or machines. Additional examples of output device 808 include a speaker, a light-emitting diode (LED) display, a liquid crystal display (LCD or OLED), or any other type of device that can generate output to a user.

Computing device 800 may include operating system 816. Operating system 816, in some examples, controls the operation of components of computing device 800, and provides an interface from various applications such as software application 822 to components of computing device 800. For example, operating system 816, in one example, facilitates the communication of various applications such as software application 822 with processors 802, communication unit 810, storage device 812, input device 806, and output device 808. Applications such as application 822 may include program instructions and/or data that are executable by computing device 800. These and other program instructions or modules may include instructions that cause computing device 800 to perform one or more of the other operations and actions described in the examples presented herein.

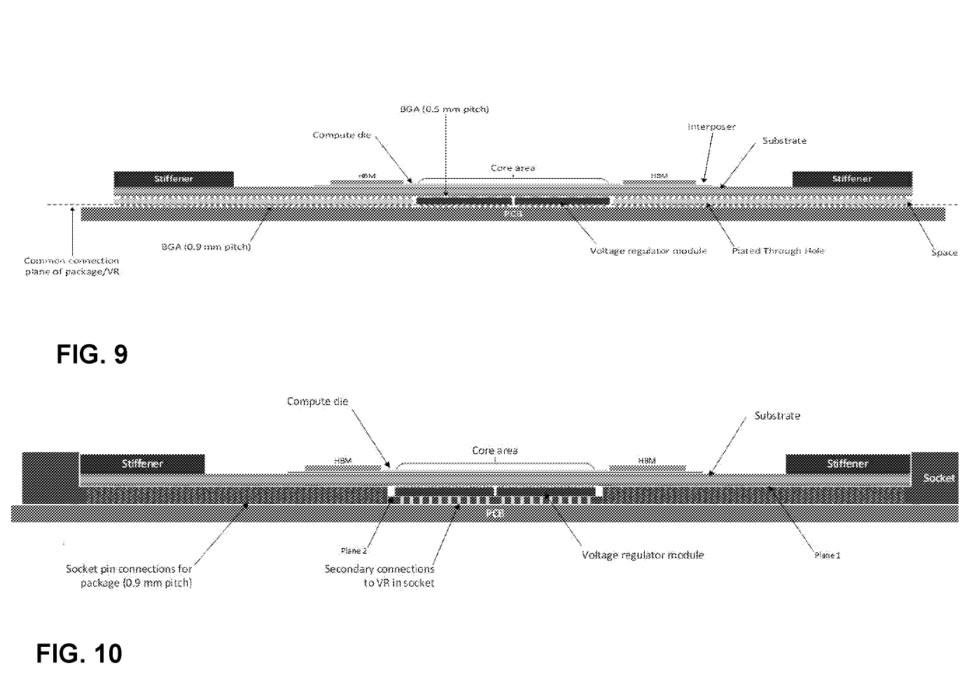

FIG. 9 is a cross-section scale view of an integrated circuit assembly having a spacer and a dual-sided voltage regulator, consistent with an example embodiment.

FIG. 10 a cross-section scale view of an integrated circuit assembly having a dual-sided voltage regulator and a socket, consistent with an example embodiment.

Process cores, bitcell arrays, memory structures, peripheral circuitry, and other circuits as described herein in particular examples may be formed in whole or in part by and/or expressed in transistors and/or lower metal interconnects (not shown) in processes (e.g., front end-of-line and/or back-end-of-line processes) such as processes to form complementary metal oxide semiconductor (CMOS) circuitry. The various blocks, neural networks, and other elements disclosed herein may be described using computer aided design tools and expressed (or represented), as data and/or instructions embodied in various computer-readable media, in terms of their behavioral, register transfer, logic component, transistor, layout geometries, and/or other characteristics.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Features of example computing devices employed in example embodiments may comprise features, for example, of a client computing device and/or a server computing device. The term computing device, in general, whether employed as a client and/or as a server, or otherwise, refers at least to a processor and a memory connected by a communication bus. A “processor” and/or “processing circuit” for example, is understood to connote a specific structure such as a central processing unit (CPU), digital signal processor (DSP), graphics processing unit (GPU), image signal processor (ISP) and/or neural processing unit (NPU), or a combination thereof, of a computing device which may include a control unit and an execution unit. In an aspect, a processor and/or processing circuit may comprise a device that fetches, interprets and executes instructions to process input signals to provide output signals. As such, in the context of the present patent application at least, this is understood to refer to sufficient structure within the meaning of 35 USC § 112 (f) so that it is specifically intended that 35 USC § 112 (f) not be implicated by use of the term “computing device,” “processor,” “processing unit,” “processing circuit” and/or similar terms; however, if it is determined, for some reason not immediately apparent, that the foregoing understanding cannot stand and that 35 USC § 112 (f), therefore, necessarily is implicated by the use of the term “computing device” and/or similar terms, then, it is intended, pursuant to that statutory section, that corresponding structure, material and/or acts for performing one or more functions be understood and be interpreted to be described at least in FIG. 1 and in the text associated with the foregoing figure(s) of the present patent application.

Some embodiments may be described, at least in part, by the following numbered clauses or by any combination thereof:

Clause 1: An assembly, comprising: an integrated circuit die; a substrate having a first mounting surface and a second mounting surface opposite the first mounting surface, the substrate electrically and physically coupled to the integrated circuit die on a first mounting surface of the die and the first mounting surface of the substrate; a voltage regulator having a first mounting surface and a second mounting surface opposite the first mounting surface, the voltage regulator electrically and physically coupled to the substrate on the second mounting surface of the substrate and the first mounting surface of the voltage regulator; and a spacer having a first mounting surface and a second mounting surface opposite the first mounting surface, the spacer electrically and physically coupled to the substrate via a plurality of electrical connections on the first mounting surface of the spacer and a plurality of electrical connections on the second mounting surface of the substrate, the spacer comprising a plurality of electrical connections passing through the spacer from the first mounting surface of the spacer to the second mounting surface of the spacer, and wherein the second mounting surface of the voltage regulator is approximately coplanar with the second mounting surface of the spacer.

Clause 2: The assembly of clause 1, further comprising a plurality of contacts on the second mounting surface of the spacer.

Clause 3: The assembly of clause 2, wherein the plurality of contacts on the second mounting surface of the spacer comprise a ball grid array (BGA).

Clause 4: The assembly of any of clauses 1-3, further comprising a printed circuit board electrically and physically coupled to the second mounting surface of the spacer, the printed circuit board further electrically and physically coupled to the second mounting surface of the voltage regulator.

Clause 5: The assembly of any of clauses 1-4, wherein the voltage regulator is operable to receive a power signal via a plurality of electrical contacts on the second mounting surface of the vertically integrated voltage regulator, and to provide one or more voltage signals to power the integrated circuit via the electrical coupling to the substrate on the first mounting surface of the voltage regulator.

Clause 6: The assembly of any of clauses 1-5, further comprising at least one additional integrated circuit die electrically and physically mounted to the substrate and powered, at least in part, by the voltage regulator.

Clause 7: The assembly of any of clauses 1-6, further comprising a stiffener mounted to the first mounting surface of the substrate.

Clause 8: The assembly of any of clauses 1-7, wherein at least a portion of the voltage regulator and at least a portion of the integrated circuit die are intersected by an axis normal to and through the first mounting surface of the voltage regulator and the first mounting surface of the integrated circuit die.

Clause 9: The assembly of any of clauses 1-8, wherein the voltage regulator comprises two or more voltage regulator modules, each operable to independently provide one or more regulated voltages.

Clause 10: The assembly of any of clauses 1-9, wherein the spacer comprises an opening formed therein for accommodating the voltage regulator.

Clause 11: The assembly of any of clauses 1-10, further comprising an interposer coupling the integrated circuit die and the substrate.

Clause 12: A method of forming an integrated circuit assembly, comprising: electrically and physically attaching a first mounting surface of an integrated circuit die to a first mounting surface of a substrate, the substrate further comprising a second mounting surface opposite the first mounting surface; electrically and physically attaching a first mounting surface of a vertically integrated voltage regulator to the substrate on the second mounting surface of the substrate, the vertically integrated voltage regulator further comprising a second mounting surface opposite the first mounting surface; and electrically and physically attaching first mounting surface of a spacer to the second mounting surface of the substrate, the spacer comprising a second mounting surface opposite the first mounting surface and further comprising a plurality of electrical connections passing through the spacer from the first mounting surface of the spacer to the second mounting surface of the spacer, such that the second mounting surface of the vertically integrated voltage regulator is approximately coplanar with the second mounting surface of the spacer.

Clause 13: The method of clause 12, further comprising electrically and physically coupling the second mounting surface of the vertically integrated voltage regulator and the second mounting surface of the spacer to a printed circuit board.

Clause 14: The method of any of clauses 11-12, wherein at least a portion of the voltage regulator and at least a portion of the integrated circuit die are intersected by an axis normal to and through the first mounting surface of the voltage regulator and the first mounting surface of the integrated circuit die.

Clause 15: An assembly, comprising: an integrated circuit die comprising a first mounting surface; a substrate having a first mounting surface and a second mounting surface opposite the first mounting surface, the first mounting surface of the substrate electrically and physically coupled to the first mounting surface of the integrated circuit die, the substrate further comprising a first plurality of electrical contact pads on the second mounting surface of the substrate; a vertically integrated voltage regulator having a first mounting surface and a second mounting surface opposite the first mounting surface, the vertically integrated voltage regulator electrically and physically coupled to the substrate on the second mounting surface of the substrate and the first mounting surface of the vertically integrated voltage regulator to provide a regulated voltage to the substrate, the voltage regulator further comprising a second plurality of electrical contact pads on the second mounting surface of the voltage regulator configured to receive an input power signal.

Clause 16: The assembly of clause 15, wherein at least one of the first plurality of electrical contact pads and the second plurality of electrical contact pads comprise at least part of a land grid array (LGA) of lands, and further comprising a Land Grid Array (LGA) socket physically and electrically coupled to a printed circuit board, the Land Grid Array (LGA) socket configured to electrically connect with at least one of the first plurality of electrical contact pads and the second plurality of electrical contact pads.

Clause 17: The assembly of clause 16, wherein the land grid array (LGA) socket comprises a cavity configured to accommodate the voltage regulator.

Clause 18: The assembly of any of clauses 15-17, wherein the at least one of the first plurality of electrical contact pads and the second plurality of electrical contact pads comprise at least part of a ball grid array (BGA) of electrical contact pads, and further comprising a printed circuit board comprising at least one array of ball grid array (BGA) contact pads, the at least one array of ball grid array (BGA) contact pads on the printed circuit board electrically and physically coupled to at least one of the first plurality of electrical contact pads and the second plurality of electrical contact pads.

Clause 19: The assembly of any of clauses 15-18, wherein at least a portion of the voltage regulator and at least a portion of the integrated circuit die are intersected by an axis normal to and through the first mounting surface of the integrated circuit die and the first mounting surface of the voltage regulator.

Clause 20: The assembly of any of clauses 15-19, further comprising a printed circuit board, the second plurality of electrical contact pads on the second mounting surface of the voltage regulator physically and electrically coupled to the printed circuit board and at least one of the first plurality of electrical contact pads on the second mounting surface of the substrate physically and electrically coupled to the printed circuit board.

Clause 21: An assembly, comprising: an integrated circuit die having a first mounting surface; a substrate having a first mounting surface and a second mounting surface opposite the first mounting surface, the first mounting surface of the integrated circuit die physically and electrically connected to the first mounting surface of the substrate, the substrate comprising a plurality of electrical contacts on the second mounting surface of the substrate configured to electrically connect with a first plurality of electrical connections in a socket; a voltage regulator having a first mounting surface and a second mounting surface opposite the first mounting surface, the voltage regulator electrically and physically coupled to the substrate on the second mounting surface of the substrate and the first mounting surface of the voltage regulator, the voltage regulator further comprising a plurality of electrical contacts on the second mounting surface of the voltage regulator configured to electrically connect with a second plurality of electrical connections in the socket.

Clause 22: The assembly of clause 21, wherein the plurality of electrical contacts on the second mounting surface of the voltage regulator comprise an array of Pin Grid Array (PGA) pins.

Clause 23: The assembly of clause 22, wherein the plurality of electrical contacts on the second mounting surface of the substrate comprise an array of Pin Grid Array (PGA) pins.

Clause 24: The assembly of any of clauses 21-23, wherein the plurality of electrical contacts on the second mounting surface of the voltage regulator comprise an array of Land Grid Array (LGA) lands.

Clause 25: The assembly of clause 24, wherein the plurality of electrical contacts on the second mounting surface of the substrate comprise an array of Land Grid Array (PGA) lands.

Clause 26: The assembly of any of clauses 21-25, further comprising a socket coupled to the plurality of electrical contacts on the second mounting surface of the voltage regulator and to the plurality of electrical contacts on the second mounting surface of the substrate.

Clause 27: The assembly of clause 26, further comprising a printed circuit board physically and electrically coupled to the socket.

Clause 28: The assembly of any of clauses 26-27, wherein the socket further comprises at least one liquid cooling channel configured to receive and return a liquid coolant.

Clause 29: The assembly of any of clauses 21-28, wherein the second plurality of electrical connections in the socket comprise high current connections having a higher contact area and/or cross-sectional area than the first plurality of electrical connections.

Clause 30: The assembly of clause 29, wherein the second plurality of electrical connections in the socket are wider in pitch than the first plurality of electrical connections in the socket.

Clause 31: The assembly of any of clauses 21-30, wherein at least a portion of the voltage regulator and at least a portion of the integrated circuit die are intersected by an axis normal to and through the first mounting surface of the integrated circuit die and the first mounting surface of the voltage regulator.

Although specific embodiments have been illustrated and described herein, any arrangement that achieve the same purpose, structure, or function may be substituted for the specific embodiments shown. This application is intended to cover any adaptations or variations of the example embodiments of the invention described herein. These and other embodiments are within the scope of the following claims and their equivalents.

What is claimed is:

1. An assembly, comprising:
an integrated circuit die;
a substrate having a first mounting surface and a second mounting surface opposite the first mounting surface, the substrate electrically and physically coupled to the integrated circuit die on a first mounting surface of the integrated circuit die and the first mounting surface of the substrate;
a voltage regulator having a first mounting surface and a second mounting surface opposite the first mounting surface, the voltage regulator electrically and physically coupled to the substrate on the second mounting surface of the substrate and the first mounting surface of the voltage regulator; and
a spacer having a first mounting surface and a second mounting surface opposite the first mounting surface, the spacer electrically and physically coupled to the substrate via a plurality of electrical connections on the first mounting surface of the spacer and a plurality of electrical connections on the second mounting surface of the substrate, the spacer comprising a plurality of electrical connections passing through the spacer from the first mounting surface of the spacer to the second mounting surface of the spacer, and wherein the second mounting surface of the voltage regulator is approximately coplanar with the second mounting surface of the spacer.

2. The assembly of claim 1, further comprising a plurality of contacts on the second mounting surface of the spacer.

3. The assembly of claim 2, wherein the plurality of contacts on the second mounting surface of the spacer comprise a ball grid array (BGA).

4. The assembly of claim 1, further comprising a printed circuit board electrically and physically coupled to the second mounting surface of the spacer, the printed circuit board further electrically and physically coupled to the second mounting surface of the voltage regulator.

5. The assembly of claim 1, wherein the voltage regulator is operable to receive a power signal via a plurality of electrical contacts on the second mounting surface of the voltage regulator, and to provide one or more voltage signals to power the integrated circuit die via the electrical coupling to the substrate on the first mounting surface of the voltage regulator.

6. The assembly of claim 1, further comprising at least one additional integrated circuit die electrically and physically mounted to the substrate and powered, at least in part, by the voltage regulator.

7. The assembly of claim 1, further comprising a stiffener mounted to the first mounting surface of the substrate.

8. The assembly of claim 1, wherein at least a portion of the voltage regulator and at least a portion of the integrated circuit die are intersected by an axis normal to and through the first mounting surface of the voltage regulator and the first mounting surface of the integrated circuit die.

9. The assembly of claim 1, wherein the voltage regulator comprises two or more voltage regulator modules, each operable to independently provide one or more regulated voltages.

10. The assembly of claim 1, wherein the spacer comprises an opening formed therein for accommodating the voltage regulator.

11. The assembly of claim 1, further comprising an interposer coupling the integrated circuit die and the substrate.

12. A method of forming an integrated circuit assembly, comprising:
electrically and physically attaching a first mounting surface of an integrated circuit die to a first mounting surface of a substrate, the substrate further comprising a second mounting surface opposite the first mounting surface;
electrically and physically attaching a first mounting surface of a vertically integrated voltage regulator to the substrate on the second mounting surface of the substrate, the vertically integrated voltage regulator further comprising a second mounting surface opposite the first mounting surface; and
electrically and physically attaching first mounting surface of a spacer to the second mounting surface of the substrate, the spacer comprising a second mounting surface opposite the first mounting surface and further comprising a plurality of electrical connections passing through the spacer from the first mounting surface of the spacer to the second mounting surface of the spacer, such that the second mounting surface of the vertically integrated voltage regulator is approximately coplanar with the second mounting surface of the spacer.

13. The method of claim 12, further comprising electrically and physically coupling the second mounting surface of the vertically integrated voltage regulator and the second mounting surface of the spacer to a printed circuit board.

14. The method of claim 12, wherein at least a portion of the vertically integrated voltage regulator and at least a portion of the integrated circuit die are intersected by an axis normal to and through the first mounting surface of the voltage regulator and the first mounting surface of the integrated circuit die.

15. An assembly, comprising:
an integrated circuit die comprising a first mounting surface;
a substrate having a first mounting surface and a second mounting surface opposite the first mounting surface, the first mounting surface of the substrate electrically and physically coupled to the first mounting surface of the integrated circuit die, the substrate further comprising a first plurality of electrical contact pads on the second mounting surface of the substrate;
and
a vertically integrated voltage regulator having a first mounting surface and a second mounting surface opposite the first mounting surface, the vertically integrated voltage regulator electrically and physically coupled to the substrate on the second mounting surface of the substrate and the first mounting surface of the vertically integrated voltage regulator to provide a regulated voltage to the substrate, the voltage regulator further comprising a second plurality of electrical contact pads on the second mounting surface of the voltage regulator configured to receive an input power signal.

16. The assembly of claim 15, wherein at least one of the first plurality of electrical contact pads and the second plurality of electrical contact pads comprise at least part of a land grid array (LGA) of lands, and further comprising a Land Grid Array (LGA) socket physically and electrically coupled to a printed circuit board, the Land Grid Array (LGA) socket configured to electrically connect with at least one of the first plurality of electrical contact pads and the second plurality of electrical contact pads.

17. The assembly of claim 16, wherein the land grid array (LGA) socket comprises a cavity configured to accommodate the vertically integrated voltage regulator.

18. The assembly of claim 15, wherein the at least one of the first plurality of electrical contact pads and the second plurality of electrical contact pads comprise at least part of a ball grid array (BGA) of electrical contact pads, and further comprising a printed circuit board comprising at least one array of ball grid array (BGA) contact pads, the at least one array of ball grid array (BGA) contact pads on the printed circuit board electrically and physically coupled to at least one of the first plurality of electrical contact pads and the second plurality of electrical contact pads.

19. The assembly of claim 15, wherein at least a portion of the vertically integrated voltage regulator and at least a portion of the integrated circuit die are intersected by an axis normal to and through the first mounting surface of the integrated circuit die and the first mounting surface of the vertically integrated voltage regulator.

20. The assembly of claim 15, further comprising a printed circuit board, the second plurality of electrical contact pads on the second mounting surface of the vertically integrated voltage regulator physically and electrically coupled to the printed circuit board and at least one of the first plurality of electrical contact pads on the second mounting surface of the substrate physically and electrically coupled to the printed circuit board.
